(19) United States
(12) Patent Application Publication
(10) Pub. No.: US 2026/0068739 A1
(43) Pub. Date: Mar. 5, 2026

(54) SEMICONDUCTOR PACKAGE

(71) Applicant: Samsung Electronics Co., Ltd., Suwon-si (KR)

(72) Inventor: Hyunsoo CHUNG, Suwon-si (KR)

(73) Assignee: Samsung Electronics Co., Ltd., Suwon-si (KR)

(21) Appl. No.: 19/068,200

(22) Filed: Mar. 3, 2025

(30) Foreign Application Priority Data
Aug. 27, 2024 (KR) 10-2024-0115214

(51) Int. Cl. H01L 23/31; H01L 23/00; H01L 23/46; H01L 23/48; H01L 25/16; H10B 80/00

(52) U.S. Cl. CPC H01L 23/315; H10B 80/00

(57) ABSTRACT

Provided is a semiconductor package including a first semiconductor chip, an inter-chip die on the first semiconductor chip in a first direction perpendicular to an upper surface of the first semiconductor chip, and a second semiconductor chip on the inter-chip die in the first direction, and the inter-chip die includes a first surface configured to face the first semiconductor chip, a second surface configured to face the second semiconductor chip, and a trench at least partially defined by the inter-chip die, the trench recessed in the first surface toward the second surface.

### CROSS-REFERENCE TO RELATED APPLICATIONS

This application claims the benefit of Korean Patent Application No. 10-2024-0115214, filed on Aug. 27, 2024, in the Korean Intellectual Property Office, the disclosure of which is incorporated herein by reference in its entirety.

### BACKGROUND

The present disclosure relates to semiconductor packages.

With development of electronic industry, a demand for high functionalization, high speed, and miniaturization of an electronic component is increasing. To correspond to such a trend, a method of stacking and mounting multiple semiconductor chips on one package wiring structure or a method of stacking a package on another package may be used. For example, a package-in-package (PIP)-type semiconductor package or a package-on-package (POP)-type semiconductor package may be used.

As an amount of heat generated in a semiconductor chip is increased with high performance of the semiconductor chip, and as a plurality of semiconductor chips becomes stacked with high-density integration of a semiconductor package, outward emission of the heat generated in the semiconductor chip is required.

### SUMMARY

Aspects of the inventive concepts may provide semiconductor packages having improved heat emission efficiency.

However, the goals to be achieved by example embodiments of the present disclosure are not limited to the objectives described above and other objects may be clearly understood from the following example embodiments by those skilled in the art.

According to an aspect, there is provided a semiconductor package including a first semiconductor chip; an inter-chip die on the first semiconductor chip in a first direction perpendicular to an upper surface of the first semiconductor chip; and a second semiconductor chip on the inter-chip die in the first direction, wherein the inter-chip die includes, a first surface configured to face the first semiconductor chip; a second surface configured to face the second semiconductor chip; and a trench at least partially defined by the inter-chip die, the trench recessed in the first surface toward the second surface.

According to another aspect, there is also provided a semiconductor package including a first semiconductor chip; an inter-chip die on the first semiconductor chip in a first direction perpendicular to an upper surface of the first semiconductor chip; and a second semiconductor chip on the inter-chip die in the first direction, wherein the inter-chip die includes, a first surface configured to face the first semiconductor chip; a second surface configured to face the second semiconductor chip; a trench at least partially defined by the inter-chip die, the trench recessed in the first surface toward the second surface; and a connection via configured to electrically connect the first semiconductor chip and the second semiconductor chip and penetrate the inter-chip die in the first direction, and an upper surface of the trench is between the first surface and the second surface in the first direction.

According to still another aspect, there is also provided a semiconductor package including a first semiconductor chip; an inter-chip die on the first semiconductor chip in a first direction perpendicular to an upper surface of the first semiconductor chip and including a first surface configured to face the first semiconductor chip and a second surface opposite to the first surface; a second semiconductor chip on the inter-chip die in the first direction; a first chip bonding film between the inter-chip die and the first semiconductor chip and configured to cover the upper surface of the first semiconductor chip; an inter-chip die lower bonding film between the first chip bonding film and the inter-chip die and configured to cover the first surface of the inter-chip die; a molding film on the inter-chip die and configured to surround the second semiconductor chip; a vertical flow path configured to penetrate the molding film in the first direction, wherein the inter-chip die includes, a trench at least partially defined by the inter-chip die, the trench recessed in the first surface toward the second surface, the trench configured to penetrate the inter-chip die lower bonding film; and a connection via extended between the first surface and the second surface in the first direction, the first chip bonding film is exposed into the trench, and the vertical flow path communicates with the trench.

Additional aspects of some example embodiments will be set forth in part in the description which follows and, in part, will be apparent from the description.

According to some example embodiments, it is possible to improve heat emission efficiency of a semiconductor package.

### BRIEF DESCRIPTION OF THE FIGURES

These and/or other aspects, features, and advantages of the inventive concepts will become apparent and more readily appreciated from the following description of example embodiments, taken in conjunction with the accompanying drawings of which:

FIG. 1 is an example layout diagram for describing a semiconductor package according to some example embodiments;

FIG. 2 is an example diagram illustrating a cross section taken along line A-A of FIG. 1;

FIG. 3 is an example diagram illustrating an enlargement of part P of FIG. 2;

FIG. 4 is an example layout diagram for describing a semiconductor package according to some other example embodiments;

FIG. 5 is an example diagram illustrating a cross section taken along line A-A of FIG. 4;

FIG. 6 is an example layout diagram for describing a semiconductor package according to still some other example embodiments;

FIG. 7 is an example layout diagram for describing a semiconductor package according to still some other example embodiments;

FIG. 8 is an example diagram illustrating a cross section taken along line A-A of FIG. 7;

FIG. 9 is an example diagram illustrating a cross section taken along line B-B of FIG. 7;

FIG. 10 is an example layout diagram for describing a semiconductor package according to still some other example embodiments;

FIG. 11 is an example diagram illustrating a cross section taken along line A-A of FIG. 10;

FIG. 12 is an example diagram illustrating a cross section taken along line B-B of FIG. 10;

FIG. 13 is a diagram illustrating an example cross section for describing a semiconductor package according to still some other example embodiments; and

FIGS. 14 through 20 are diagrams illustrating an intermediate operation for describing a method of manufacturing a semiconductor package according to some example embodiments.

### DETAILED DESCRIPTION

Before example embodiments are described, terms or words used in the present disclosure and the accompanying claims are not to be limited to general definitions or dictionary definitions. The terms and words are to be construed under a principle that an inventor may appropriately define a concept of a term in order to describe their inventive concepts in the best way. Thus, since example embodiments described in the present disclosure and configurations illustrated in the accompanying drawings are merely some example embodiments and do not represent all of the technical spirit of the present disclosure, it should be understood that various equivalents and modifications that may replace the example embodiments and configurations may be present at the time of filing the application of the present disclosure.

In the following descriptions, terms in a singular form include terms in a plural form unless an apparently and contextually conflicting description is present. Terms such as “including” or “comprising” is to indicate that a feature, a number, an operation, an action, an element, a component, or a combination thereof is present. It should be understood that the terms are not to exclude in advance a possibility that one or more other features, numbers, operations, actions, elements, components, or combinations thereof may be present or added.

In addition, it should be noted in advance that an expression such as an upper side, an upper portion, a lower side, a lower portion, a side surface, a front surface, or a rear surface is based on directions illustrated in the drawings and that the expression may be changed when a direction of a corresponding object is changed. Shapes, sizes, or the like of elements in the drawings may be exaggerated for clearer description.

Hereinafter, some example embodiments of the present disclosure will be described with reference to the drawings.

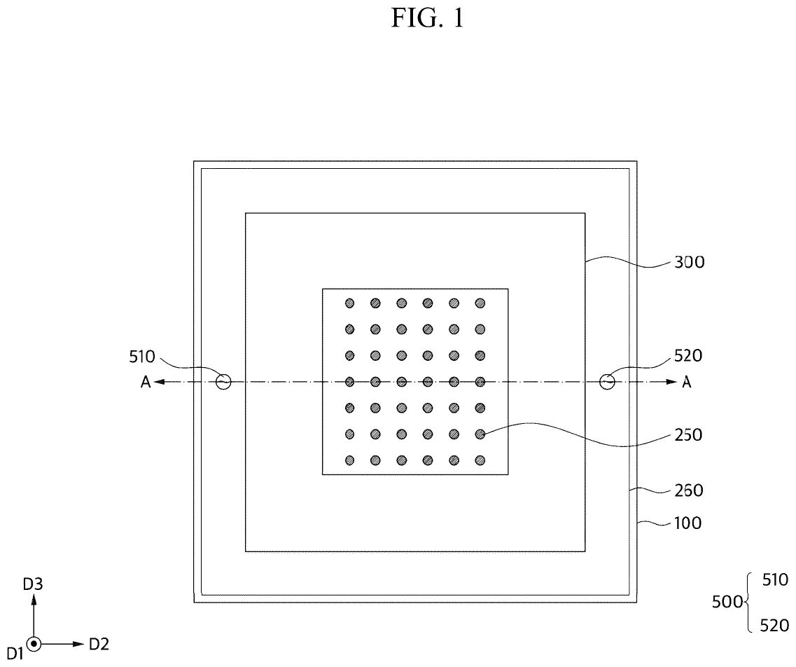

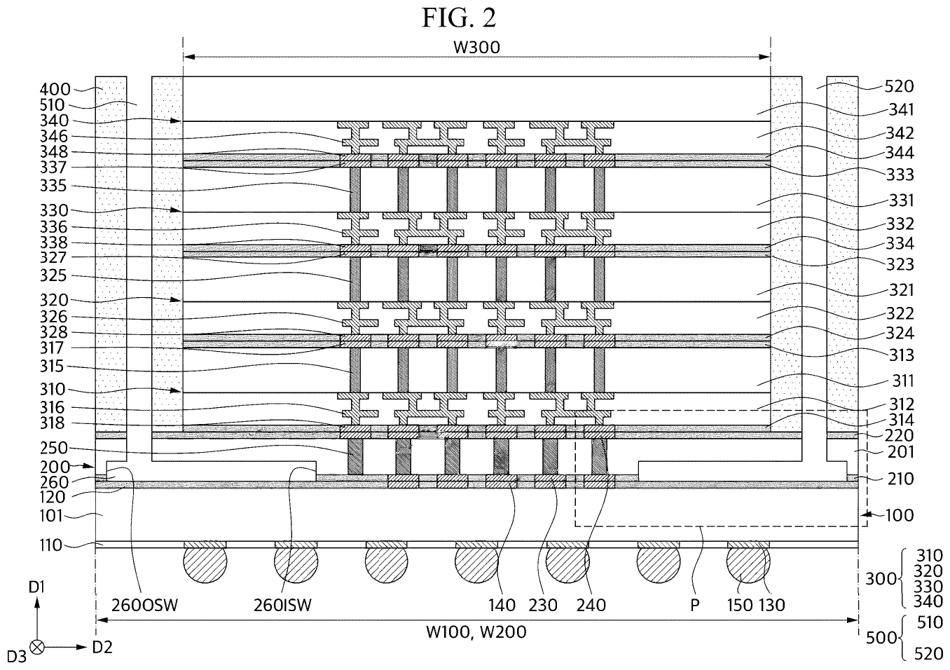

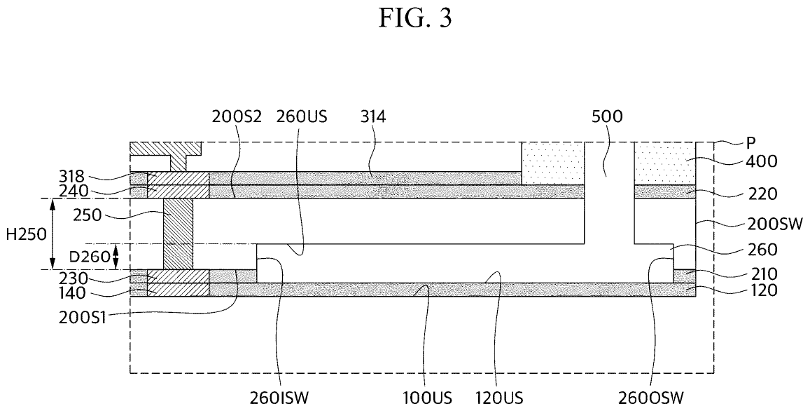

FIG. 1 is an example layout diagram for describing a semiconductor package according to some example embodiments. FIG. 2 is an example diagram illustrating a cross section taken along line A-A of FIG. 1. FIG. 3 is an example diagram illustrating an enlargement of part P of FIG. 2.

Referring to FIGS. 1 through 3, the semiconductor package according to some example embodiments may include a first semiconductor chip 100, an inter-chip die 200, a trench 260, a second semiconductor chip 300, a molding film 400, and a flow path 500.

According to some example embodiments, the first semiconductor chip 100, the inter-chip die 200, and the second semiconductor chip 300 may be vertically stacked. For example, the first semiconductor chip 100, the inter-chip die 200, and the second semiconductor chip 300 may be sequentially stacked in a first direction D1 perpendicular to an upper surface 100US of the first semiconductor chip.

According to some example embodiments, the first semiconductor chip 100 may be disposed below the inter-chip die 200 and the second semiconductor chip 300. The first semiconductor chip 100 may be electrically connected to the inter-chip die 200 and the second semiconductor chip 300.

According to some example embodiments, the first semiconductor chip 100 may be an integrated circuit (IC) in which hundreds to millions or more of semiconductor devices are integrated in one chip. As an example, the first semiconductor chip 100 may include a logic chip. The first semiconductor chip 100 may be a microprocessor, an analog element, a digital signal processor, or an application processor. The first semiconductor chip 100 may be a central processing unit (CPU), a graphic processing unit (GPU), a field-programmable gate array (FPGA), the digital signal processor, an encryption processor, the microprocessor, the application processor (AP) such as a microcontroller or the like. However, it is merely an example. As another example, the first semiconductor chip 100 may be a memory chip such as a volatile memory (e.g., a dynamic random access memory (DRAM)), a non-volatile memory (e.g., a read-only memory or a flash memory), or the like.

According to some example embodiments, the first semiconductor chip 100 may include a first chip body part 101, a lower passivation film 110, a first chip bonding film 120, a first chip lower connection pad 130, a first chip upper connection pad 140, and an external connection bump 150.

According to some example embodiments, the first chip body part 101 may be, for example, bulk silicon or silicon-on-insulator (SOI). As another example, the first chip body part 101 may be a silicon substrate. As still another example, the first chip body part 101 may include silicon germanium, silicon germanium on insulator (SGOI), indium antimonide, lead telluride, indium arsenide, gallium arsenide, or gallium antimonide, but it is merely an example.

According to some example embodiments, the first chip body part 101 may include a conductive area, for example, a well doped with an impurity or a structure doped with the impurity. The first chip body part 101 may have various element isolation structures such as a shallow trench isolation (STI) structure.

According to some example embodiments, the first chip body part 101 may be formed of at least one material selected from a phenolic resin, an epoxy resin, or polyimide. The first chip body part 101 may include at least one material selected from tetrafunctional epoxy, polyphenylene ether, epoxy/polphenylene oxide, bimaleimide triazine (BT), Thermount, cyanate ester, and/or a liquid crystal polymer.

According to some example embodiments, the first chip body part 101 may include a resin (e.g., prepreg, Ajinomoto Build-up Film (ABF), FR-4, or bismaleimide triazine (BT)) impregnated together with an inorganic filler in a core material such as a glass fiber (e.g., a glass cloth or a glass fabric).

According to some example embodiments, the first chip body part 101 may include various types of a plurality of individual devices and an inter-layer insulation film. An individual device may include various microelectronic devices, for example, a metal-oxide-semiconductor filed effect transistor (MOFSET) such as a complementary metal-insulator-semiconductor (CMOS) transistor, a system large-scale integration (LSI) device, the flash memory, the dynamic random access memory (DRAM), a static random access memory (SRAM), an electrically erasable and programmable read-only memory (EEPROM), a phase-change random access memory (PRAM), a resistive random access memory (RRAM), an image sensor such as a CMOS imaging sensor (CIS), a micro-electro-mechanical system (MEMS), an active element, a passive element, and/or the like.

Although not illustrated, the first chip body part 101 may include a wiring structure electrically connected to the first chip lower connection pad 130 and the first chip upper connection pad 140. The wiring structure in the first chip body part 101 may connect a wiring pattern extended in a second direction D2 or a third direction D3 and each wiring pattern and include a wiring via extended in the first direction D1. For example, the wiring structure in the first chip body part 101 may have a multilayer structure in which two or more wiring patterns or two or more wiring vias are stacked alternately. The wiring structure in the first chip body part 101 may include a conductive material, for example, copper (Cu), aluminum (Al), silver (Ag), tin (Sn), gold (Au), nickel (Ni), lead (Pb), titanium (Ti), or an alloy thereof, but it is merely an example.

According to some example embodiments, the lower passivation film 110 may be disposed below the first chip body part 101. The lower passivation film 110 may protect the wiring structure in the first chip body part 101 and other structures from external impact or humidity. The first chip lower connection pad 130 may be disposed in the lower passivation film 110. The lower passivation film 110 may expose a portion of a lower surface of the first chip lower connection pad 130. The lower passivation film 110 may include solder resist.

According to some example embodiments, the first chip bonding film 120 may be disposed on the first chip body part 101. The first chip bonding film 120 may cover the upper surface 100US of the first semiconductor chip. The first chip bonding film 120 may be disposed between the first chip body part 101 and the inter-chip die 200. The first chip bonding film 120 may be disposed between the first chip body part 101 and an inter-chip die lower bonding film 210. The first chip bonding film 120 may surround the first chip upper connection pad 140.

According to some example embodiments, the first chip bonding film 120 may be formed of different materials among silicon oxide, silicon nitride, silicon carbonitride, and/or silicon oxycarbonitride. The first chip bonding film 120 may include a non-conductive film (NCF), a non-conductive paste (NCP), an insulating polymer, or an epoxy resin, but it is merely an example. The first chip bonding film 120 may be tape for fixing the first semiconductor chip 100 and the inter-chip die 200 to each other. The first chip bonding film 120 may be, for example, tape including an epoxy component.

According to some example embodiments, the first chip lower connection pad 130 may be disposed in the lower passivation film 110. The first chip lower connection pad 130 may be surrounded by the lower passivation film 110. The first chip lower connection pad 130 may be connected to an external connection bump 150. The first chip lower connection pad 130 may be disposed on a lower surface of the first chip body part 101. The first chip lower connection pad 130 may be electrically connected to the wiring structure in the first chip body part 101. The first chip lower connection pad 130 may include at least one selected from aluminum (Al), copper (Cu), nickel (Ni), tungsten (W), platinum (Pt), and/or gold (Au).

According to some example embodiments, the first chip upper connection pad 140 may be disposed in the first chip bonding film 120. The first chip upper connection pad 140 may be surrounded by the first chip bonding film 120. The first chip upper connection pad 140 may be connected to an inter-chip die lower pad 230. The first chip upper connection pad 140 may be in contact with the inter-chip die lower pad 230. The first chip upper connection pad 140 may be in contact with the inter-chip die lower pad 230 to electrically connect the first semiconductor chip 100 and the inter-chip die 200. The first chip upper connection pad 140 may include at least one selected from aluminum (Al), copper (Cu), nickel (Ni), tungsten (W), platinum (Pt), and/or gold (Au).

According to some example embodiments, the external connection bump 150 may be disposed below the first lower connection pad 130. The external connection bump 150 may be in contact with the first chip lower connection pad 130. The external connection bump 150 may be a solder ball or a solder bump. The external connection bump 150 may have, for example, a spherical shape or an ovally spherical shape, but it is merely an example. The number of external connection bumps 150, an interval between the external connection bumps 150, disposition or a shape of the external connection bump 150, or the like is not limited to an illustration and may also vary depending on a design. The external connection bump 150 may include, for example, tin (Sn), indium (In), bismuth (Bi), antimony (Sb), copper (Cu), silver (Ag), zinc (Zn), lead (Pb), and/or a combination thereof, but it is merely an example.

According to some example embodiments, the external connection bump 150 may electrically connect the first semiconductor chip 100 to an external device. The external connection bump 150 may send an electric signal for the first semiconductor chip 100 and the second semiconductor chip 300. The external connection bump 150 may send, into the semiconductor package, a signal that is input to the first semiconductor chip 100 and the second semiconductor chip 300. The external connection bump 150 may send to an outside of the semiconductor package, a signal that is output by the first semiconductor chip 100 and the second semiconductor chip 300.

According to some example embodiments, the inter-chip die 200 may be stacked on the first semiconductor chip 100. The inter-chip die 200 may be disposed on the upper surface 100US of the first semiconductor chip. The inter-chip die 200 may be disposed between the first semiconductor chip 100 and the second semiconductor chip 300. The inter-chip die 200 may connect the first semiconductor chip 100 and the second semiconductor chip 300.

According to some example embodiments, a width W200 of the inter-chip die may be equal to a width W100 of the first semiconductor chip in the second direction D2. A side surface 200SW of the inter-chip die and a side wall of the first semiconductor chip 100 may be disposed on an identical plane, e.g., may be coplanar. The width W200 of the inter-chip die may be larger than a width W300 of the second semiconductor chip in the second direction D2. The side surface 200SW of the inter-chip die may be disposed outward of a side wall of the second semiconductor chip 300.

According to some example embodiments, the inter-chip die 200 may include an inter-chip die body part 201, a connection via 250, and the trench 260.

According to some example embodiments, the inter-chip die body part 201 may be, for example, bulk silicon or silicon-on-insulator (SOI). The inter-chip die body part 201 may include silicon germanium, silicon germanium on insulator (SGOI), indium antimonide, lead telluride, indium arsenide, gallium arsenide, and/or gallium antimonide, but it is merely an example. The inter-chip die body part 201 may surround the connection via 250.

According to some example embodiment, the connection via 250 may electrically connect the first semiconductor chip 100 and the second semiconductor chip 300. The connection via 250 may be disposed between the inter-chip die lower pad 230 and an inter-chip die upper pad 240. The connection via 250 may penetrate the inter-chip die 200. The connection via 250 may be extended in the first direction D1. The connection via 250 may be extended between a first surface 200S1 of the inter-chip die and a second surface 200S2 of the inter-chip die.

According to some example embodiments, when the inter-chip die 200 is viewed in the first direction D1, the connection via 250 may be surrounded by the trench 260. When the inter-chip die 200 is viewed in the first direction D1, the connection via 250 may be disposed inward of the trench 260. The connection via 250 may be disposed inward of an inner side surface 260ISW of the trench 260. The connection via 250 may be disposed closer to a center of the inter-chip die 200 than the inner side surface 260ISW of the trench 260.

According to some example embodiments, a height H250 of the connection via may be larger than a depth D260 of the trench in the first direction D1. The height H250 of the connection via may refer to a distance between the inter-chip die lower pad 230 and the inter-chip die upper pad 240. The depth D260 of the trench may refer to a distance from the first surface 200S1 of the inter-chip die to an upper surface 260US of the trench.

According to some example embodiments, the connection via 250 may include, as an example, at least one selected from aluminum (Al), copper (Cu), nickel (Ni), tungsten (W), platinum (Pt), and gold (Au). As another example, the connection via 250 may include at least one of titanium (Ti), titanium nitride (TiN), tantalum (Ta), tantalum nitride (TaN), ruthenium (Ru), cobalt (Co), manganese (Mn), tungsten nitride (WN), nickel (Ni), nickel boride (NiB), copper (Cu), a copper (Cu) alloy such as copper-tin (CuSn), copper-magnesium (CuMg), copper-nickel (CuNi), copper-palladium (CuPd), copper-gold (CuAu), copper-rhenium (CuRe), and copper-tungsten (CuW), tungsten (W), a tungsten (W) alloy, nickel (Ni), ruthenium (Ru), and/or cobalt (Co), but it is merely an example.

According to some example embodiments, the trench 260 may be formed from the first surface 200S1 of the inter-chip die toward the second surface 200S2 of the inter-chip die. The trench 260 may form, in the inter-chip die 200, an empty space in which an upper surface 120US of the first chip bonding film is exposed. The trench 260 may be formed in the inter-chip die 200.

According to some example embodiments, when the inter-chip die 200 is viewed in the first direction D1, the trench 260 may surround the connection via 250. When the inter-chip die 200 is viewed in the first direction D1, the trench 260 may have a quadrangular ring shape. The trench 260 may be disposed to be spaced apart from the center of the inter-chip die 200 further than the connection via 250. The trench 260 may be disposed closer to an edge of the inter-chip die 200 than the connection via 250. The trench 260 may be disposed to be further adjacent to a side surface 200SW of the inter-chip die than the connection via 250. The inner side surface 260ISW of the trench may face the connection via 250. An outer side surface 260OSW of the trench may face the side surface 200SW of the inter-chip die.

According to some example embodiments, the trench 260 may be defined by the inner side surface 260ISW, the outer side surface 260OSW, and the upper surface 260US. The inner side surface 260ISW and the outer side surface 260OSW of the trench 260 may face each other. For example, the inner side surface 260ISW and the outer side surface 260OSW may face each other in the second direction D2 which crosses the first direction D1.

According to some example embodiments, the upper surface 260US of the trench may be an inner surface of the trench 260, which faces the first semiconductor chip 100. The upper surface 260US of the trench may be disposed between the first surface 200S1 and the second surface 200S2 of the inter-chip die in the first direction. In other words, the trench 260 may not completely penetrate the inter-chip die 200 in the first direction D1 and may be formed as a portion of the inter-chip die 200 is removed from the first surface 200S1 toward the second surface 200S2.

According to some example embodiments, the trench 260 may penetrate the inter-chip die lower bonding film 210. The trench 260 may penetrate the inter-chip die lower bonding film 210 to expose the first bonding film 120 on the first semiconductor chip 100 into the trench 260.

According to some example embodiments, the trench 260 may communicate with the flow path 500. For example, the trench 260 may communicate with vertical flow paths 510 and 520 extended in the first direction D1 on the trench 260. The trench 260 may receive and discharge a cooling fluid through the flow path 500. Efficiency of cooling the first semiconductor chip 100 in contact with the trench 260 may be improved with the cooling fluid which flows in the trench 260. As being in direct contact with the cooling fluid which flows through the trench 260, the first semiconductor chip 100 below the second semiconductor chip 300 may be cooled.

According to some example embodiments, the inter-chip die lower bonding film 210 may be disposed on the first surface 200S1 of the inter-chip die. The inter-chip die lower bonding film 210 may cover the first surface 200S1 of the inter-chip die. The inter-chip die lower bonding film 210 may be disposed between the inter-chip die 200 and the first chip bonding film 120. The inter-chip die lower bonding film 210 may surround the inter-chip die lower pad 230. The inter-chip die lower pad 230 may be in contact with and connected to the first chip upper connection pad 140.

According to some example embodiments, the inter-chip die 200 may be bonded to the first semiconductor chip 100 through the inter-chip die lower bonding film 210. The inter-chip die lower bonding film 210 may be in contact with the first chip bonding film 120. The inter-chip die lower bonding film 210 may not overlap the trench 260 in the first direction D1.

According to some example embodiments, an inter-chip die upper bonding film 220 may be disposed on the second surface 200S2 of the inter-chip die. The inter-chip die upper bonding film 220 may cover the second surface 200S2 of the inter-chip die. The inter-chip die upper bonding film 220 may be disposed between the inter-chip die 200 and a first sub-chip lower bonding film 314. The inter-chip die upper bonding film 220 may surround the inter-chip die upper pad 240. The inter-chip die upper pad 240 may be in contact with and connected to a first sub-chip lower connection pad 318.

According to some example embodiments, the inter-chip die 200 may be bonded to the second semiconductor chip 300 through the inter-chip die upper bonding film 220. Further specifically, the inter-chip die 200 may be bonded to a first sub-chip 310 through the inter-chip die upper bonding film 220. The inter-chip die upper bonding film 220 may be in contact with the first sub-chip lower bonding film 314. The inter-chip die upper bonding film 220 may be penetrated by the flow path 500.

According to some example embodiments, since materials included in the inter-chip die lower bonding film 210 and the inter-chip die upper bonding film 220 are substantially identical to a material included in the first chip bonding film 120, a description for the materials included in the inter-chip die lower bonding film 210 and the inter-chip die upper bonding film 220 will be hereinafter omitted.

According to some example embodiments, since materials included in the inter-chip die lower pad 230 and the inter-chip die upper pad 240 are substantially identical to a material included in the first chip upper connection pad 140, a description for the materials included in the inter-chip die lower pad 230 and the inter-chip die upper pad 240 will be hereinafter omitted.

According to some example embodiments, the second semiconductor chip 300 may be stacked on the inter-chip die 200. The second semiconductor chip 300 may be disposed on the second surface 200S2 of the inter-chip die. The second semiconductor chip 300 may be surrounded by the molding film 400.

According to some example embodiments, the second semiconductor chip 300 may be an integrated circuit (IC) in which hundreds to millions or more of semiconductor devices are each integrated in one chip. For example, the second semiconductor chip 300 may include a memory chip such as the volatile memory or the non-volatile memory. The second semiconductor chip 300 may be a high bandwidth memory (HBM).

According to some example embodiments, the second semiconductor chip 300 may include a plurality of sub-chips. For example, the second semiconductor chip 300 may include the first sub-chip 310, a second sub-chip 320, a third sub-chip 330, and a fourth sub-chip 340. The second semiconductor chip 300 may include a plurality of memory chips stacked in the first direction D1. As an example, the first sub-chip 310, the second sub-chip 320, the third sub-chip 330, and the fourth sub-chip 340 may be memory chips. FIG. 2 illustrates that the second semiconductor chip 300 includes four sub-chips, but it is merely an example. The number of chips included in the second semiconductor chip 300 may be variously changed depending on example embodiments.

According to some example embodiments, the first sub-chip 310, the second sub-chip 320, the third sub-chip 330, and the fourth sub-chip 340 each may be a non-volatile memory chip such as the dynamic random access memory (DRAM) or the static random access memory (SRAM). As another example, the first sub-chip 310, the second sub-chip 320, the third sub-chip 330, and the fourth sub-chip 340 each may be a non-volatile memory chip such as the flash memory, the phase-change RAM (PRAM), a magnetoresistive RAM (MRAM), a ferroelectric RAM (FeRAM), or the resistive RAM (RRAM).

According to some example embodiments, the first sub-chip 310, the second sub-chip 320, the third sub-chip 330, and the fourth sub-chip 340 may be stacked on the inter-chip die 200 in the first direction D1. The first sub-chip 310, the second sub-chip 320, the third sub-chip 330, and the fourth sub-chip 340 may be electrically connected to each other or electrically connected to the inter-chip die 200 through first to fourth sub-chip lower connection pads 318, 328, 338, and 348 and first to third sub-chip upper connection pads 317, 327, and 337.

According to some example embodiments, the first sub-chip 310 may include a first substrate 311, a first device layer 312, a first penetration via 315, a first sub-chip upper connection pad 317, and the first sub-chip lower connection pad 318. The first sub-chip 310 may be connected to the inter-chip die 200 through the first sub-chip lower connection pad 318. The first sub-chip 310 and the inter-chip die 200 may be connected by a hybrid bonding scheme. For example, the first sub-chip lower connection pad 318 and the inter-chip die upper pad 240 may be directly bonded together, and the first sub-chip lower bonding film 314 and the inter-chip die upper bonding film 220 may be directly bonded together.

According to some example embodiments, the first substrate 311 may be, for example, bulk silicon or silicon-on-insulator (SOI). As another example, the first substrate 311 may be a silicon substrate. As still another example, the first substrate 311 may include silicon germanium, silicon germanium on insulator (SGOI), indium antimonide, lead telluride, indium arsenide, gallium arsenide, and/or gallium antimonide, but it is merely an example.

According to some example embodiments, the first substrate 311 may include a conductive area, for example, a well doped with an impurity or a structure doped with the impurity. The first substrate 311 may have various element isolation structures such as the shallow trench isolation (STI) structure.

According to some example embodiments, the first device layer 312 may be disposed below the first substrate 311. The first device layer 312 may include various types of a plurality of individual devices and an inter-layer insulation film. An individual device may include various microelectronic devices, for example, the metal-oxide-semiconductor filed effect transistor (MOFSET) such as the complementary metal-insulator-semiconductor (CMOS) transistor, the system large-scale integration (LSI) device, the flash memory, the DRAM, the SRAM, the EEPROM, the PRAM, the RRAM, an image sensor such as the CMOS imaging sensor (CIS), the micro-electro-mechanical system (MEMS), an active element, a passive element, or the like.

According to some example embodiments, the individual devices of the first device layer 312 may be electrically connected to the conductive area which is formed in the first substrate 311. The individual devices of the first device layer 312 may be electrically separated from other neighboring individual devices by insulation films. The first device layer 312 may include a first wiring structure 316 electrically connecting at least two of the plurality of individual devices or connecting the plurality of individual devices and the conductive area of the first substrate 311.

According to some example embodiments, an insulation layer for protecting the first wiring structure 316 and other structures in the first device layer 312 from external impact of humidity may be formed on the first device layer 312. The insulation layer may expose a portion of an upper surface of the first sub-chip lower connection pad 318.

According to some example embodiments, the first penetration via 315 may penetrate the first substrate 311. The first penetration via 315 may be extended from an upper surface of the first substrate 311 toward a lower surface thereof. The first penetration via 315 may be connected to the first wiring structure 316 which is provided in the first device layer 312.

According to some example embodiments, the first penetration via 315 may include a barrier film formed on a surface of a pillar shape and a buried conductive layer filling an inside of the barrier film. The barrier film may include at least one of titanium (Ti), titanium nitride (TiN), tantalum (Ta), tantalum nitride (TaN), ruthenium (Ru), cobalt (Co), manganese (Mn), tungsten nitride (WN), nickel (Ni), and/or nickel boride (NiB), but it is merely an example. The buried conductive layer may include at least one of copper (Cu), a copper (Cu) alloy such as copper-tin (CuSn), copper-magnesium (CuMg), copper-nickel (CuNi), copper-palladium (CuPd), copper-gold (CuAu), copper-rhenium (CuRe), and copper-tungsten (CuW), tungsten (W), a tunsten (W) alloy, nickel (Ni), ruthenium (Ru), and/or cobalt (Co), but it is merely an example.

According to some example embodiments, an insulation film may be additionally interposed between the first substrate 311 and the first penetration via 315. The insulation film may include the oxide film, the nitride film, the carbide film, the polymer, or the combination thereof, but it is merely an example.

According to some example embodiments, the first wiring structure 316 may include a metallic wiring layer and a via plug. For example, the first wiring structure 316 may have a multilayer structure in which two or more metallic wiring layers or two or more via plugs are stacked alternately.

According to some example embodiments, the first sub-chip lower connection pad 318 may be disposed on the first device layer 312. The first sub-chip lower connection pad 318 may be electrically connected to the first wiring structure 316 in the first device layer 312. The first sub-chip lower connection pad 318 may be electrically connected to the first penetration via 315 through the first wiring structure 316. The first sub-chip lower connection pad 318 may include at least one selected from aluminum (Al), copper (Cu), nickel (Ni), tungsten (W), platinum (Pt), and/or gold (Au).

According to some example embodiments, the first sub-chip lower connection pad 318 may be surrounded by the first sub-chip lower bonding film 314. The first sub-chip lower bonding film 314 may be disposed on the first device layer 312. The first sub-chip lower bonding film 314 may cover a lower surface of the first device layer 312.

According to some example embodiments, the first sub-chip upper connection pad 317 which is electrically connected to the first penetration via 315 may be formed on the upper surface of the first substrate 311. The first sub-chip upper connection pad 317 may be formed of a material identical to that of the first sub-chip lower connection pad 318. Although not illustrated, an upper passivation layer may be formed on the upper surface of the first substrate 311 so as to surround a portion of a side surface of the first sub-chip upper connection pad 317. The upper passivation layer may expose a portion of an upper surface of the first sub-chip upper connection pad 317.

According to some example embodiments, the first sub-chip upper connection pad 317 may be surrounded by a first sub-chip upper bonding film 313. The first sub-chip upper bonding film 313 may be disposed on the first substrate 311. The first sub-chip upper bonding film 313 may cover the upper surface of the first substrate 311.

According to some example embodiments, the second sub-chip 320 may be disposed on the first sub-chip 310. According to some example embodiments, the second sub-chip 320 may include a second substrate 321, a second device layer 322, a second penetration via 325, a second sub-chip upper connection pad 327, and a first sub-chip lower connection pad 328. The second sub-chip 320 may be electrically connected to the first sub-chip 310 through the second sub-chip lower connection pad 328 and the first sub-chip upper connection pad 317 which are disposed between the first sub-chip 310 and the second sub-chip 320. The second sub-chip 320 may be connected to the first sub-chip 310 by the hybrid bonding scheme.

According to some example embodiments, the third sub-chip 330 may be disposed on the second sub-chip 320. The third sub-chip 330 may include a third substrate 331, a third device layer 332, a third penetration via 335, a third sub-chip upper connection pad 337, and a third sub-chip lower connection pad 338. The third sub-chip 330 may be electrically connected to the second sub-chip 320 through the third sub-chip lower connection pad 338 and the second sub-chip upper connection pad 327 which are disposed between the second sub-chip 320 and the third sub-chip 330. The third sub-chip 330 may be connected to the second sub-chip 320 by the hybrid bonding scheme.

According to some example embodiments, the fourth sub-chip 340 may be disposed on the third sub-chip 330. The fourth sub-chip 340 may include a fourth substrate 341, a fourth device layer 342, and a fourth sub-chip lower connection pad 348. The fourth sub-chip 340 may be electrically connected to the third sub-chip 330 through the fourth sub-chip lower connection pad 348 and the third sub-chip upper connection pad 337 which are disposed between the third sub-chip 330 and the fourth sub-chip 340. The fourth sub-chip 340 may be connected to the third sub-chip 330 by the hybrid bonding scheme. The fourth sub-chip 340 may not include a penetration via and an upper connection pad unlike first to third sub-chips 310-330.

According to some example embodiments, since descriptions for the second sub-chip 320, the third sub-chip 330, and the fourth sub-chip 340 are substantially identical to a description for the first sub chip 310, the descriptions for the second sub-chip 320, the third sub-chip 330, and the fourth sub-chip 340 will be omitted.

According to some example embodiments, the molding film 400 may be stacked on the inter-chip die 200. The molding film 400 may cover the second semiconductor chip 300. The molding film 400 may include, for example, a polymer such as a resin. For example, the molding film 400 may include an epoxy molding compound (EMC), but it is merely an example.

According to some example embodiments, the flow path 500 may penetrate the molding film 400. The flow path 500 may penetrate the molding film 400 to communicate with the trench 260. According to some example embodiments, the flow path 500 may include the vertical flow paths 510 and 520. The vertical flow paths 510 and 520 may penetrate the molding film 400 in the first direction D1. The vertical flow paths 510 and 520 may include a vertical inlet flow path 510 and a vertical outlet flow path 520.

According to some example embodiments, the vertical inlet flow path 510 and the vertical outlet flow path 520, for example, may be disposed to be spaced apart in the second direction D2. However, it is merely an example. FIGS. 1 and 2 illustrate that the vertical inlet flow path 510 and the vertical outlet flow path 520 are spaced apart in the second direction D2 with the connection via 250 of the inter-chip die 200 in between. However, it is merely an example. The vertical inlet flow path 510 and the vertical outlet flow path 520 may be disposed side by side at on an identical side of the connection via 250.

According to some example embodiment, the cooling fluid which has flowed in through the flow path 500 may flow in the trench 260. The cooling fluid may be in direct contact with the upper surface 120US of the first chip bonding film in the trench 260 to cool heat generated in the first semiconductor chip 100 below the first chip bonding film 120. Thus, a cooling characteristic may be improved.

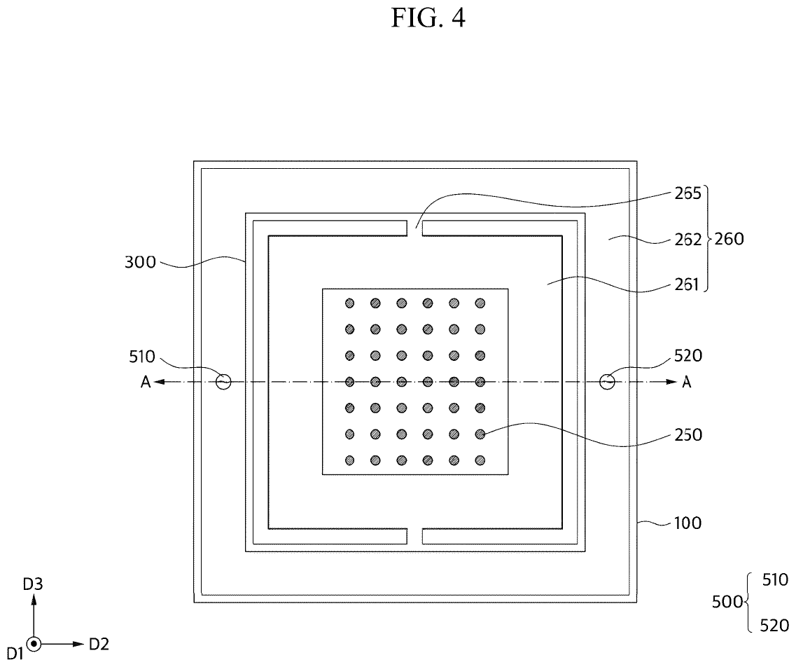

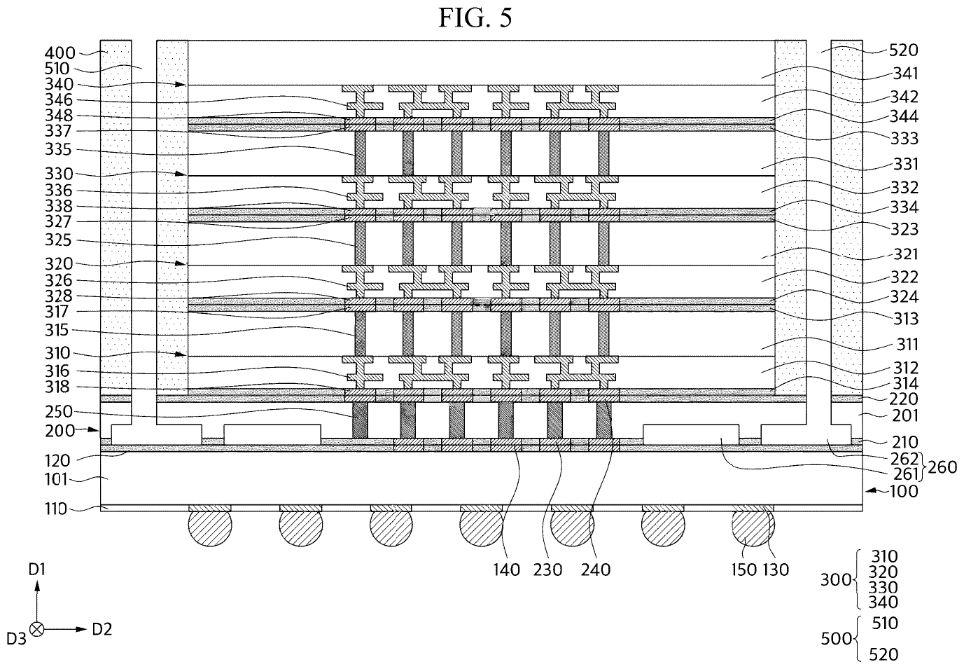

FIG. 4 is an example layout diagram for describing a semiconductor package according to some other example embodiments. FIG. 5 is an example diagram illustrating a cross section taken along line A-A of FIG. 4. In order to describe the semiconductor package according to some other example embodiments, a description will mainly focus on a point different from that described above with reference to FIGS. 1 through 3.

Referring to FIGS. 4 and 5, the trench 260 may include a first trench 261, a second trench 262, and a connection trench 265. When the inter-chip die 200 is viewed in the first direction D1, e.g., a top down view, each of the first trench 261 and the second trench 262 may have a quadrangular ring shape. The connection trench 265 may connect the first trench 261 and the second trench 262. The connection trench 265 may communicate with the first trench 261 and the second trench 262. FIG. 4 illustrates that the connection trench 265 is extended in the third direction D3 to connect the first trench 261 and the second trench 262, but it is merely an example. A direction in which the connection trench 265 is extended, the number of disposed connection trenches 265, or the like may be variously changed depending on example embodiments.

According to some example embodiments, the first trench 261 may be disposed closer to a center of the inter-chip die 200 of the second trench 262 than the second trench 262. The second trench 262 may be disposed closer to an edge of the inter-chip die 200 than the first trench 261. When the inter-chip die 200 is viewed in the first direction D1, the first trench 261 may surround the connection via 250. When the inter-chip die 200 is viewed in the first direction D1, the second trench 262 may surround the first trench 261. In some example embodiments, the shape of the first trench 261 may correspond to the shape of the second trench 262.

According to some example embodiments, the flow path 500 may be disposed on the second trench 262. The flow path 500 may communicate with the second trench 262. The flow path 500 may overlap the second trench 262 in the first direction D1. The flow path 500 may not overlap the first trench 261 in the first direction D1. Since the second trench 262 overlaps the molding film 400 in the first direction D1, and since the flow path 500 penetrates the molding film 400, the flow path 500 may communicate with the second trench 262. Since the first trench 261 does not overlap the molding film 400 in the first direction D1, the flow path 500 penetrating the molding film 400 may not communicate with the first trench 261. In some example embodiments, the first trench 261 may not be overlapped by the molding film 400 in the first direction. In some example embodiments, the first trench 261 may be vertically overlapped by the second semiconductor ship 300.

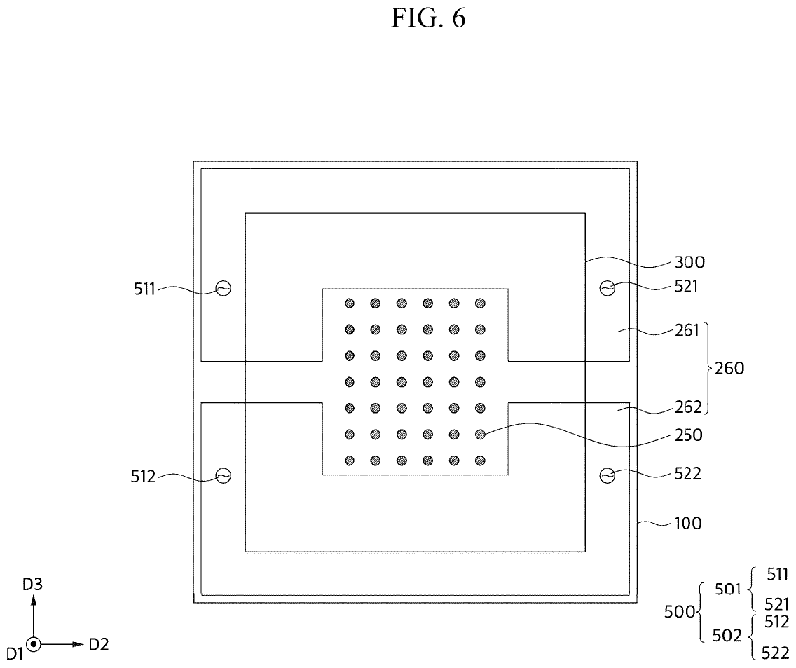

FIG. 6 is an example layout diagram for describing a semiconductor package according to still some other example embodiments. In order to describe the semiconductor package according to still some other example embodiments, a description will mainly focus on a point different from that described above with reference to FIGS. 1 through 3.

Referring to FIG. 6, the trench 260 may include the first trench 261 and the second trench 262 which are spaced apart from each other. The first trench 261 and the second trench 262 may individually include divided empty spaces. The first trench 261 and the second trench 262 may not be connected to each other. Thus, each of a first flow path 501 communicating with the first trench 261 and a second flow path 502 communicating with the second trench 262 may be disposed. The first trench 261 and the second trench 262 may be spaced apart in the third direction D3 around a center portion to which the connection via 250 is disposed.

According to some example embodiments, the first flow path 501 may include a first vertical inlet flow path 511 and a first vertical outlet flow path 521. The first vertical inlet flow path 511 and the first vertical outlet flow path 521 each may communicate with the first trench 261 to supply a cooling fluid to the first trench 261 and receive a fluid discharged from the first trench 261 after cooling.

According to some example embodiments, the second flow path 502 may include a second vertical inlet flow path 512 and a second vertical outlet flow path 522. The second vertical inlet flow path 512 and the second vertical outlet flow path 522 each may communicate with the second trench 262 to supply the cooling fluid to the second trench 262 and receive a fluid discharged from the second trench 262 after cooling.

According to some example embodiments, an area of the first semiconductor chip 100 which has a larger amount of generated heat may be relatively greatly cooled by using the first trench 261 and the second trench 262 of which areas overlapping the first semiconductor chip 100 in the first direction D1 are distinguished from each other. Thus, cooling efficiency may be improved because cooling may be adjusted with the first trench 261 and the second trench 262 depending on an amount of the generated heat.

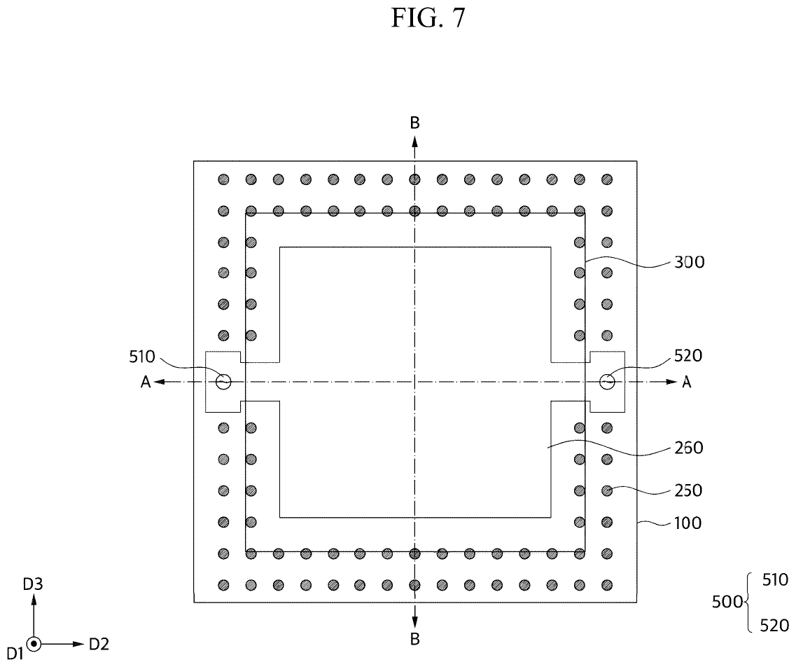

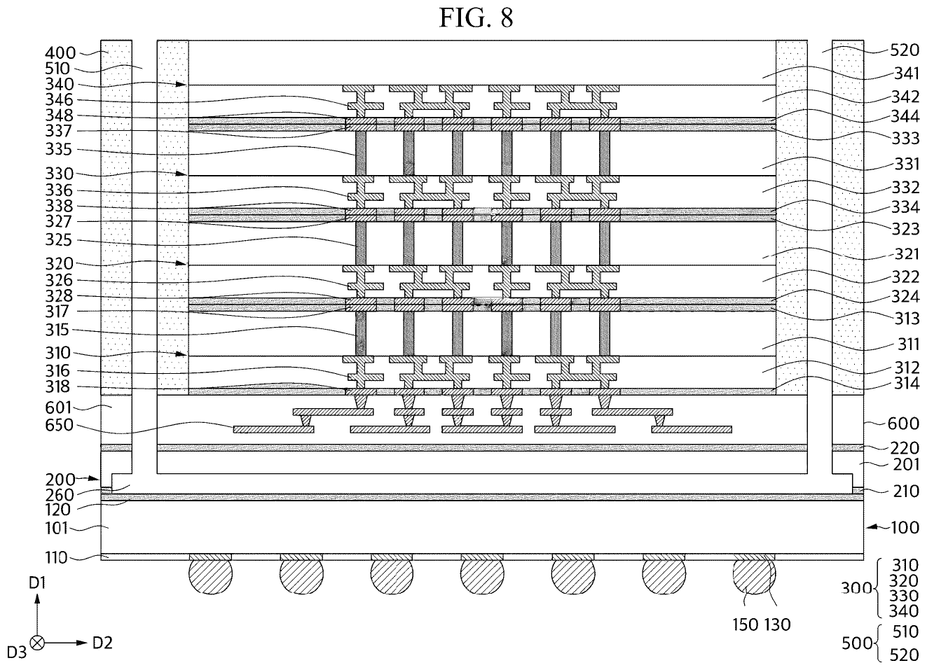

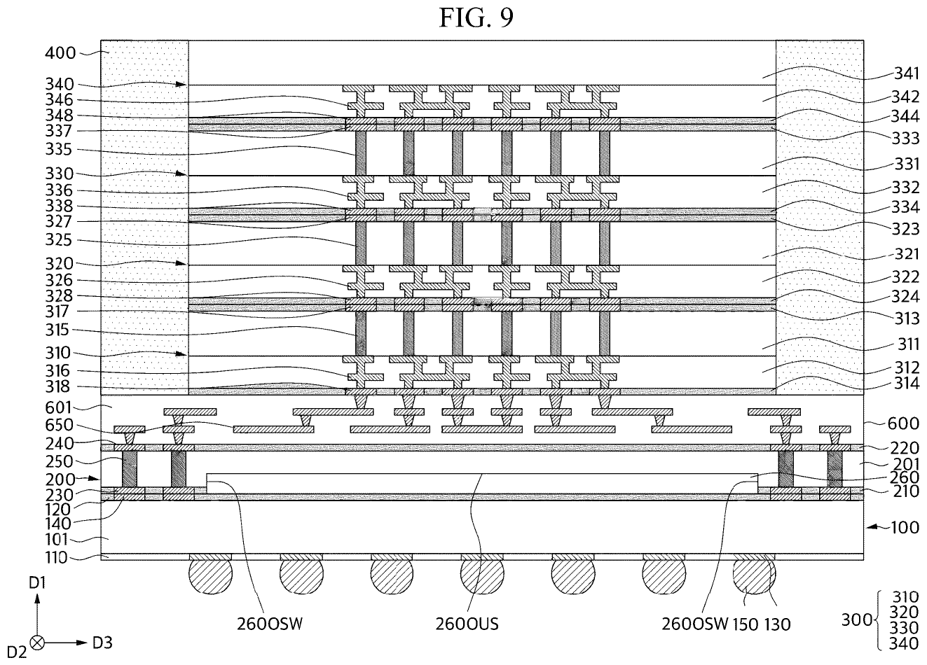

FIG. 7 is an example layout diagram for describing a semiconductor package according to still some other example embodiments. FIG. 8 is an example diagram illustrating a cross section taken along line A-A of FIG. 7. FIG. 9 is an example diagram illustrating a cross section taken along line B-B of FIG. 7. In order to describe the semiconductor package according to still some other example embodiments, a description will mainly focus on a point different from that described above with reference to FIGS. 1 through 3.

Referring to FIGS. 7 through 9, the trench 260 may be disposed to be further adjacent to a center of the inter-chip die 200 than the connection via 250. When the inter-chip die 200 is viewed in the first direction D1, the trench 260 may be surrounded by the connection via 250. The trench 260 may be disposed to be spaced apart from an edge of the inter-chip die 200 further than the connection via 250. The trench 260 may be disposed to be spaced apart from the side surface 200SW (of FIG. 3) of the inter-chip die further than the connection via 250.

According to some example embodiments, when the inter-chip die 200 is viewed in the first direction D1, the trench 260 which overlaps a center portion of the first semiconductor chip 100 in the first direction D1 may have a quadrangular shape. The trench 260 may be defined by the upper surface 260US and the outer side surface 260OSW. As having the quadrangular shape, not a quadrangular ring shape, the trench 260 may include only the outer side surface 260OSW, not an inner side surface. The outer side surface 260OSW of the trench may face the connection via 250.

According to some example embodiments, when the inter-chip die 200 is viewed in the first direction D1, the connection via 250 may surround the trench 260. The connection via 250 may be disposed to be further adjacent to the edge of the inter-chip die 200 than the trench 260. The connection via 250 may be disposed so as not to overlap the flow path 500 in the first direction D1.

According to some example embodiments, a redistribution die 600 may be disposed between the inter-chip die 200 and the second semiconductor chip 300. The redistribution die 600 may electrically connect the second semiconductor chip 300 and the connection via 250 of the inter-chip die 200. When the semiconductor package is viewed in the first direction D1, penetration vias 315, 325, and 335 and lower connection pads 318, 328, 338, and 348 of the second semiconductor chip 300 may be disposed to a center portion. On the other hand, when the inter-chip die 200 is viewed in the first direction D1, the connection via 250 may be disposed on an edge side. In other words, the penetration vias 315, 325, and 335 and the lower connection pads 318, 328, 338 of the second semiconductor chip 300 may not overlap the connection via 250 of the inter-chip die 200 in the first direction D1. Thus, in order to electrically connect the penetration vias 315, 325, and 335, the lower connection pads 318, 328, 338, and 348 of the second semiconductor chip 300, and the connection via 250 of the inter-chip die 200, the redistribution die 600 may be disposed between the inter-chip die 200 and the second semiconductor chip 300.

According to some example embodiments, the redistribution die 600 may include a redistribution substrate 601 and a redistribution structure 650. According to some example embodiments, the redistribution substrate 601 may be, for example, bulk silicon or silicon-on-insulator (SOI). The redistribution substrate 601 may include silicon germanium, silicon germanium on insulator (SGOI), indium antimonide, lead telluride, indium arsenide, gallium arsenide, and/or gallium antimonide, but it is merely an example.

According to some example embodiments, the redistribution structure 650 may electrically connect the first sub-chip lower connection pad 318 and the inter-chip die upper pad 240. The redistribution structure 650 may connect a wiring pattern extended in the second direction D2 or the third direction D3 and each wiring pattern and include a wiring via extended in the first direction D1. For example, the redistribution structure 650 may have a multilayer structure in which two or more wiring patterns or two or more wiring vias are stacked alternately. The redistribution structure 650 may include a conductive material, for example, copper (Cu), aluminum (Al), silver (Ag), tin (Sn), gold (Au), nickel (Ni), lead (Pb), titanium (Ti), or an alloy thereof, but it is merely an example.

According to some example embodiments, the flow path 500 may penetrate the molding film 400 and the redistribution die 600 to communicate with the trench 260. The flow path 500 may penetrate the inter-chip die upper bonding film 220.

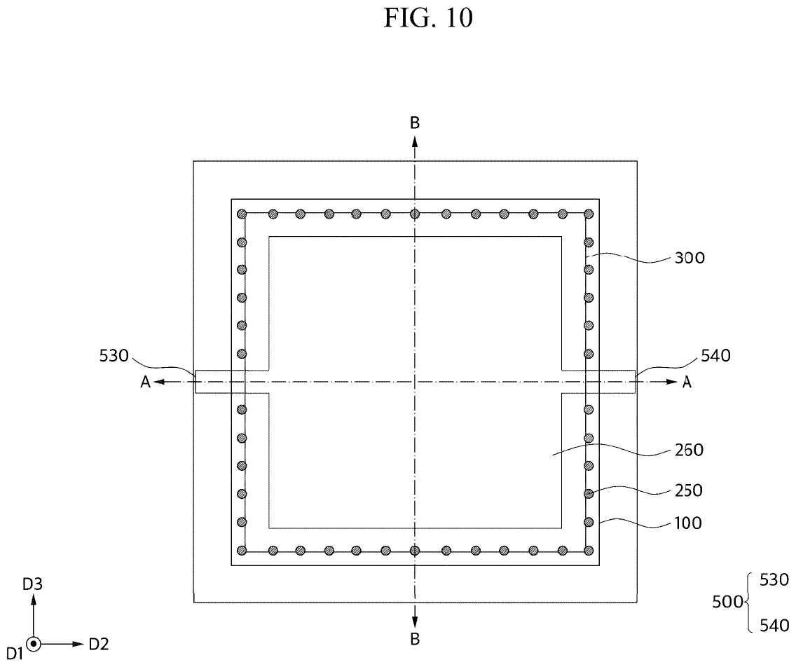

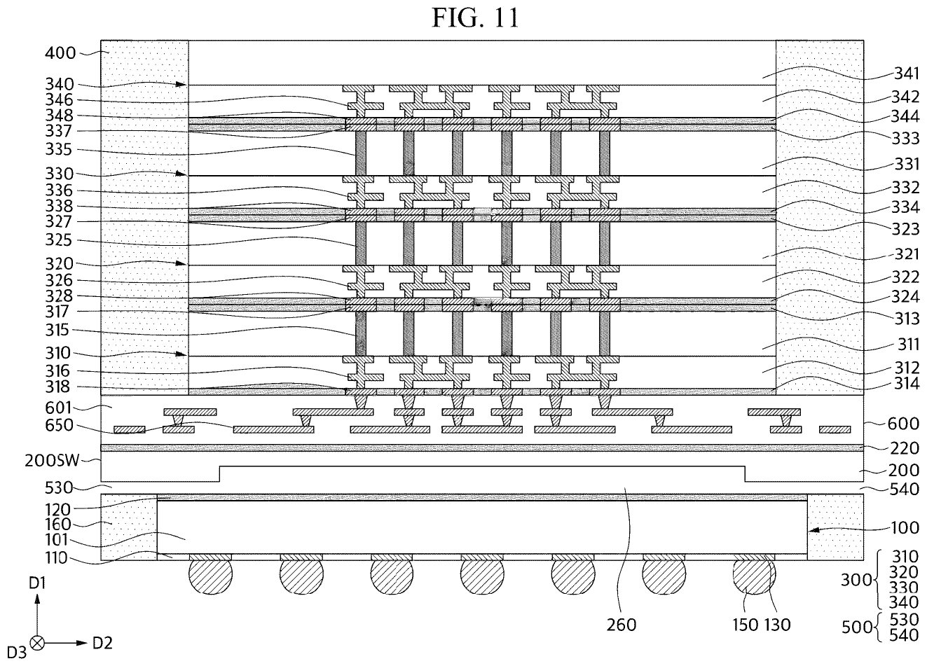

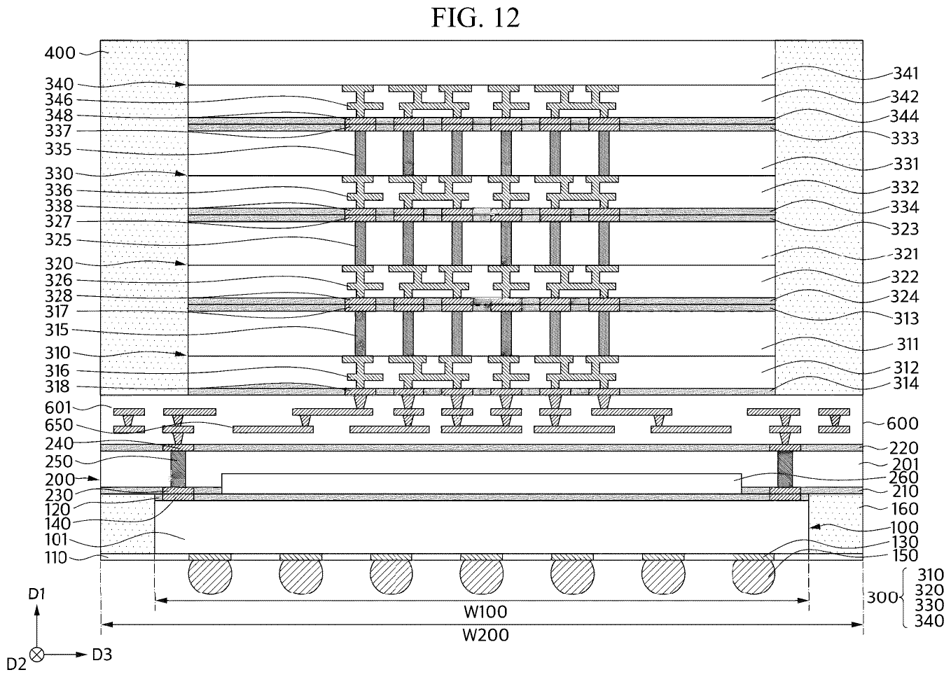

FIG. 10 is an example layout diagram for describing a semiconductor package according to still some other example embodiments. FIG. 11 is an example diagram illustrating a cross section taken along line A-A of FIG. 10. FIG. 12 is an example diagram illustrating a cross section taken along line B-B of FIG. 10. In order to describe the semiconductor package according to still some other example embodiments, a description will mainly focus on a point different from that described above with reference to FIGS. 7 through 9.

Referring to FIGS. 10 through 12, the flow path 500 may include horizontal flow paths 530 and 540. The horizontal flow paths 530 and 540 may be extended from the side surface 200SW of the inter-chip die toward the trench 260. For example, the horizontal flow paths 530 and 540 may be extended in the second direction D2 from side surfaces 200SW of the inter-chip die, which are disposed in the second direction D2, toward the trench 260.

According to some example embodiments, the width W200 of the inter-chip die may be larger than the width W100 of the first semiconductor chip in the second direction D2. Due to a manufacturing process of forming the horizontal flow paths 530 and 540 to the inter-chip die 200 and disposing the inter-chip die 200 on the first semiconductor chip 100, the width W200 of the inter-chip die may be formed to be larger than the width W100 of the first semiconductor chip 100. A first chip molding film 160 may be disposed below the inter-chip die 200 so as to surround the first semiconductor chip 100. The first chip molding film 160 may include a material identical to that of the molding film 400, but it is merely an example.

According to some example embodiment, the connection via 250 may overlap the first semiconductor chip 100 in the first direction D1. Since the connection via 250 is to electrically connect the first semiconductor chip 100 and the redistribution structure 650, the connection via 250 may be disposed to overlap the first semiconductor chip 100 in the first direction D1 so as to be disposed on the first chip upper connection pad 140 on the first semiconductor chip 100. However, it is merely an example. For example, when the connection via 250 does not overlap the first semiconductor chip 100 in the first direction D1, when the inter-chip die 200 is viewed in the first direction D1, and when the connection via 250 is disposed outward of the first semiconductor chip 100, a redistribution structure may be additionally disposed between the inter-chip die 200 and the first semiconductor chip 100. The redistribution structure may be formed so that the connection via 250 of the inter-chip die 200 and the first semiconductor chip 100 are electrically connected.

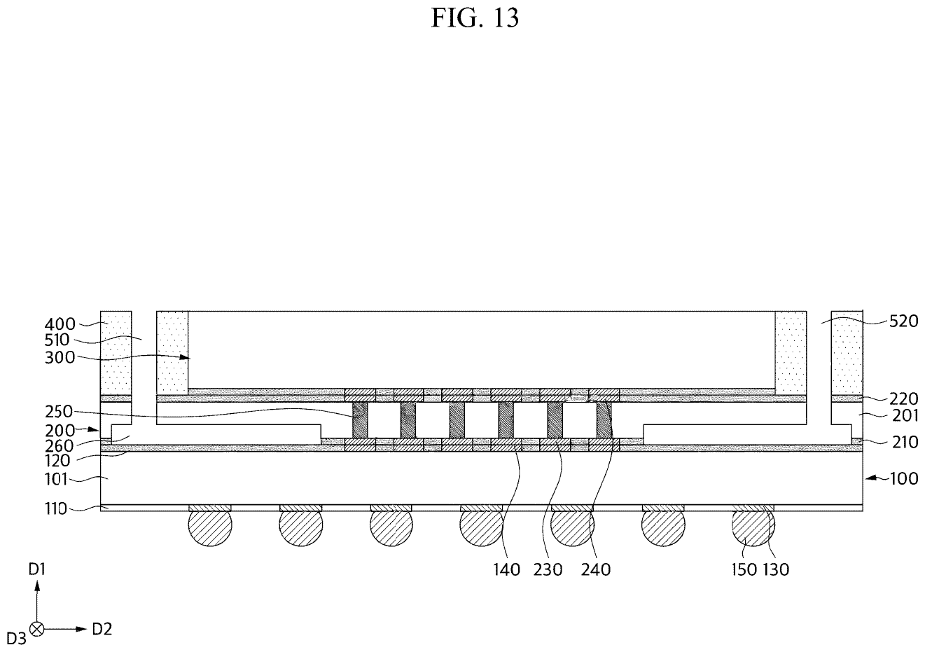

FIG. 13 is an example diagram illustrating a cross section for describing a semiconductor package according to still some other example embodiments. In order to describe the semiconductor package according to still some other example embodiments, a description will mainly focus on a point different from that described above with reference to FIGS. 1 through 3.

Referring to FIG. 13, the second semiconductor chip 300 may not include a plurality of sub-chips and may include only one chip. The second semiconductor chip 300 may not include a penetration via for sending and receiving a signal to and from chips disposed above and below.

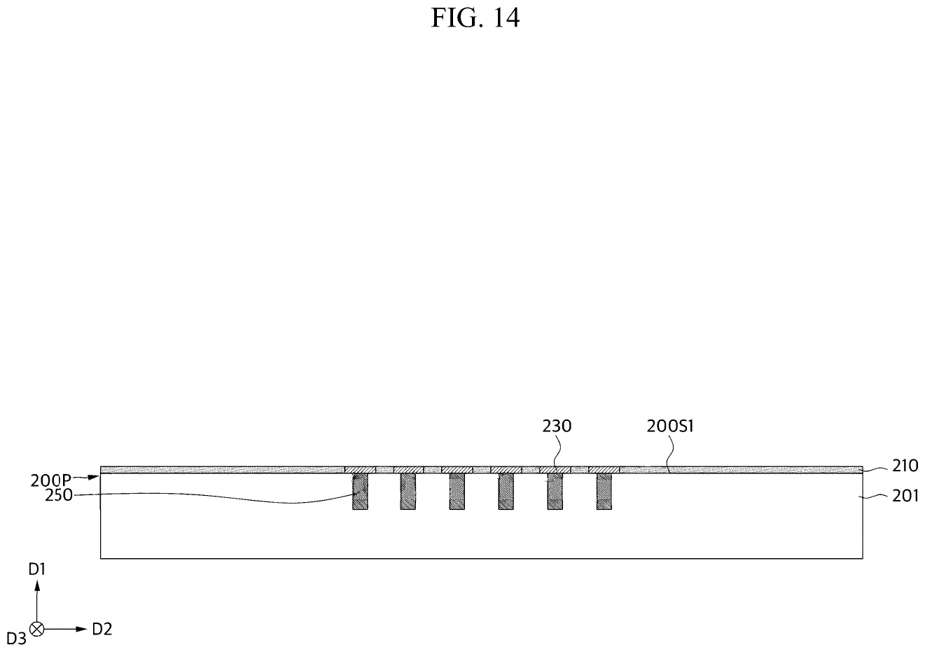

FIGS. 14 through 20 are diagrams illustrating an intermediate operation for describing a method of manufacturing a semiconductor package according to some example embodiments. In addition, for reference, FIGS. 14 through 20 illustrate the intermediate operation for describing the method of manufacturing the semiconductor package which is illustrated in FIG. 2.

Referring to FIG. 14, the connection via 250 may be formed to an inter-chip die body part 201 of a pre-inter-chip die 200P. The inter-chip die lower bonding film 210 and the inter-chip die lower pad 230 may be formed on a first surface 200S1 of the pre-inter-chip die.

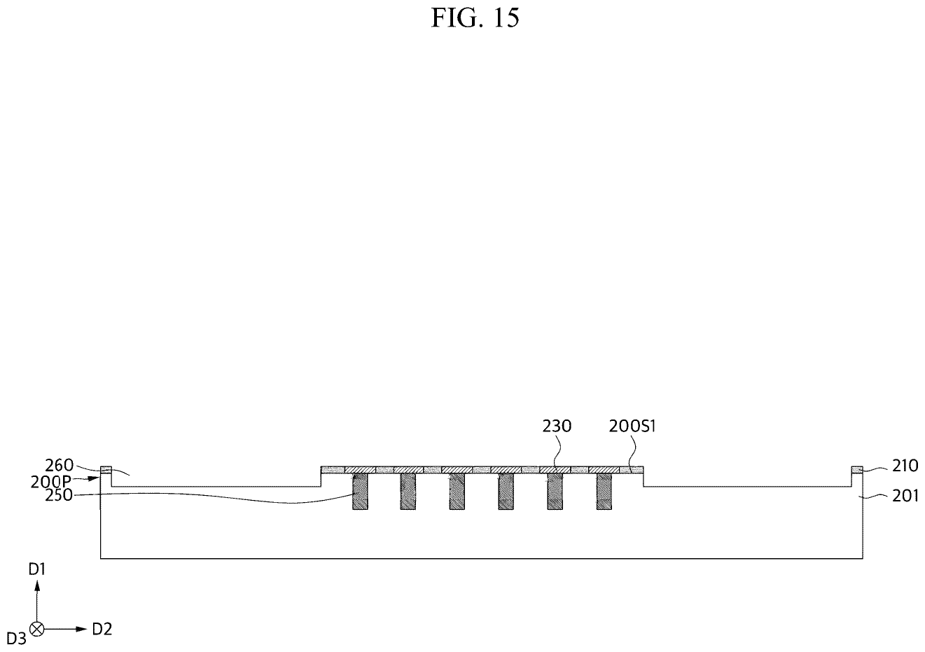

Then, referring to FIG. 15, the trench 260 may be formed from the first surface 200S1 of the pre-inter-chip die toward an inside of the inter-chip die body part 201. The trench 260 may be formed so as to penetrate the inter-chip die lower bonding film 210 which is formed in advance on the first surface 200S1 of the pre-inter-chip die. The trench 260 may be formed through, for example, an etching process.

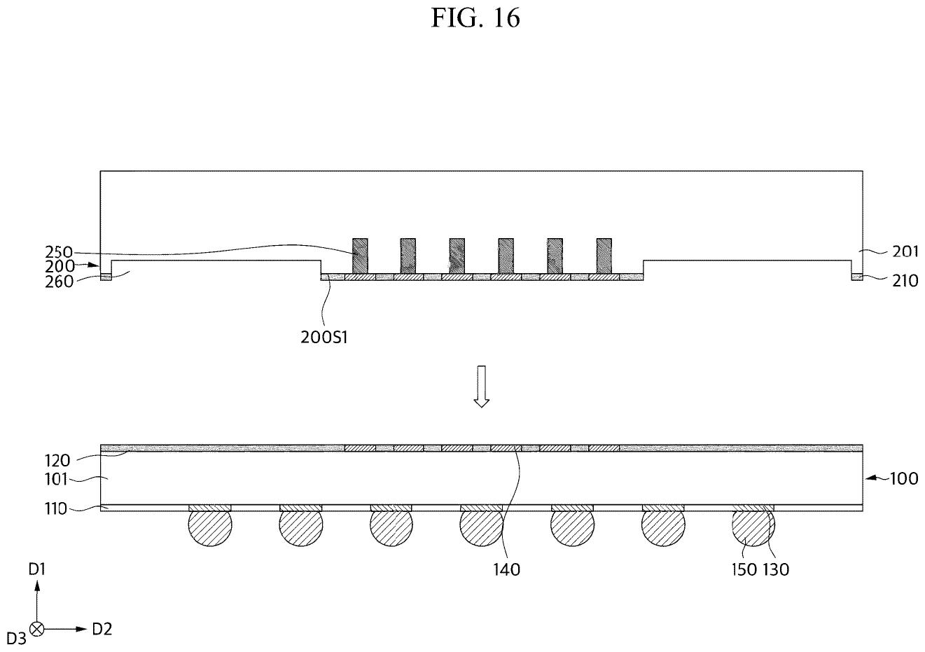

Then, referring to FIG. 16, the pre-inter-chip die 200P may be bonded on the first semiconductor chip 100 so that the first surface 200S1 of the pre-inter-chip die faces the first semiconductor chip 100. The pre-inter-chip die 200P may be aligned and bonded on the first semiconductor chip 100 so that the trench 260 faces the first chip bonding film 120 on the first semiconductor chip 100.

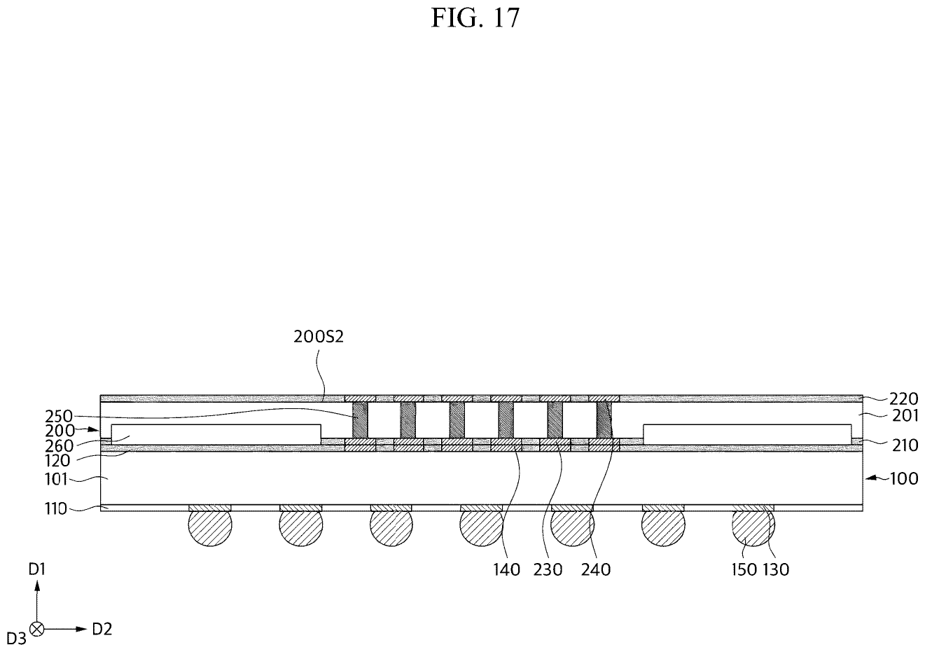

Then, referring to FIG. 17, a portion of the inter-chip die body part 201 may be removed so that the connection via 250 in the inter-chip die body part 201 is exposed. The inter-chip die upper bonding film 220 and the inter-chip die upper pad 240 may be formed on the second surface 200S2 of the inter-chip die.

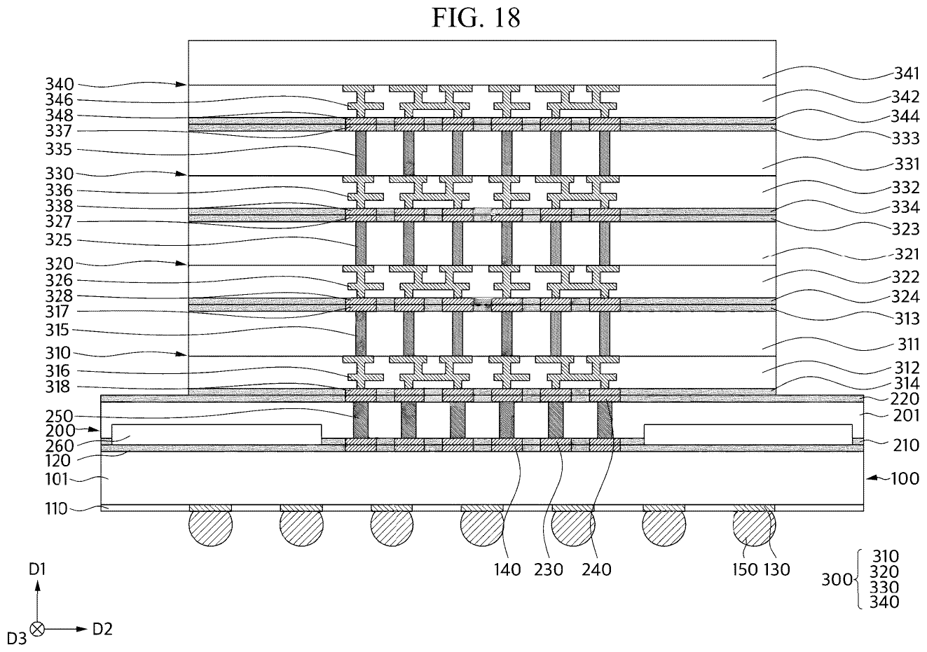

Then, referring to FIG. 18, the second semiconductor chip 300 may be stacked on the inter-chip die 200. The first sub-chip 310 to the fourth sub-chip 340 may be sequentially stacked in the first direction D1.

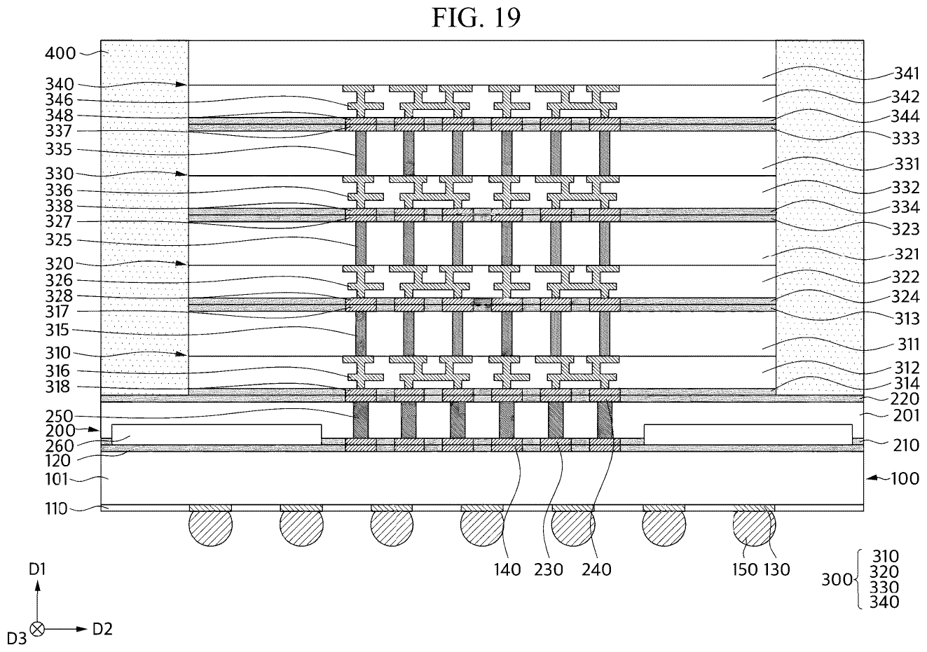

Then, referring to FIG. 19, the molding film 400 which surrounds the second semiconductor chip 300 may be formed on the inter-chip die 200.

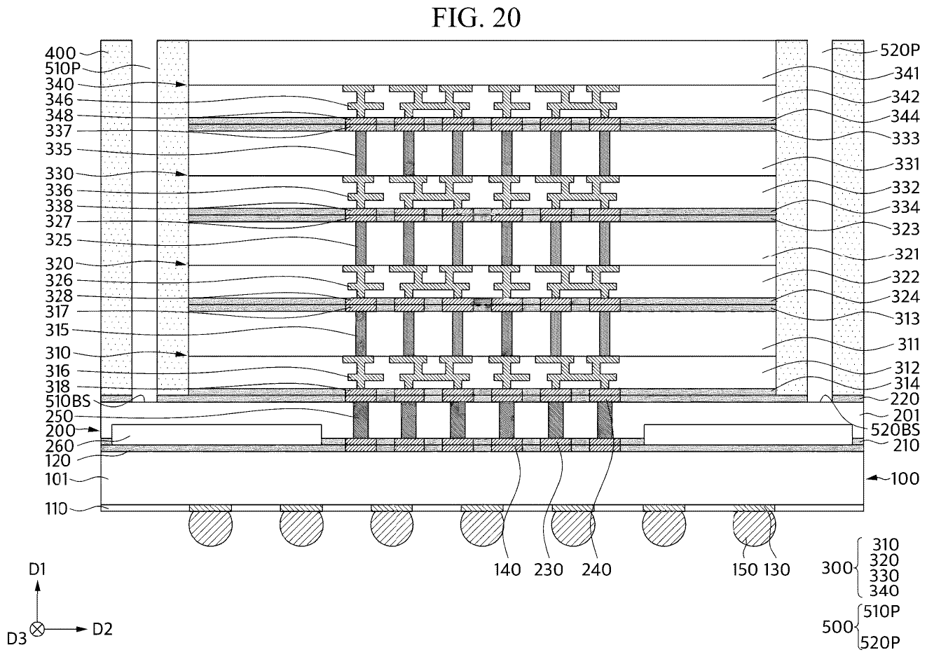

Then, referring to FIG. 20, a pre-flow path 500P penetrating the molding film 400 may be formed. The pre-flow path 500P may penetrate the molding film 400 and the inter-chip die upper bonding film 220. Floor surfaces 510BS and 520BS of the pre-flow path may expose the inter-chip die body part 201 of the inter-chip die 200.

Then, referring to FIGS. 2 and 20, a portion of the inter-chip die body part 201 which is exposed through the floor surfaces 510BS and 520BS of the pre-flow path may be removed, so that the trench 260 and the flow path 500 may communicate with each other. Since respective etch selectivities of materials individually included in the molding film 400 and the inter-chip die 200 are different, the pre-flow path 500P which penetrates the molding film 400 may be formed earlier, and the inter-chip die 200 which is exposed into the pre-flow path 500P may be sequentially removed. Through this, the flow path 500 which communicates with the trench 260 may be formed.

The various example embodiments of the present disclosure have been described above in detail, but the scope of the present disclosure is not limited thereto. It will be apparent to those skilled in the art that various changes and modifications may be allowed within a range of the technical spirit of the present disclosure. In addition, the above-described example embodiments may be implemented without a portion of elements thereof, and each of the example embodiments may be implemented in combination with another.

What is claimed is:

1. A semiconductor package comprising:
a first semiconductor chip;
an inter-chip die on the first semiconductor chip in a first direction perpendicular to an upper surface of the first semiconductor chip; and
a second semiconductor chip on the inter-chip die in the first direction,
wherein the inter-chip die includes,
a first surface configured to face the first semiconductor chip;
a second surface configured to face the second semiconductor chip; and
a trench at least partially defined by the inter-chip die, the trench recessed in the first surface toward the second surface.

2. The semiconductor package of claim 1, further comprising:
a molding film configured to surround the second semiconductor chip on the inter-chip die; and
a vertical flow path configured to penetrate the molding film in the first direction and communicate with the trench.

3. The semiconductor package of claim 1, further comprising:
a horizontal flow path configured to penetrate the inter-chip die in a second direction crossing the first direction and communicate with the trench.

4. The semiconductor package of claim 3, wherein a width of the inter-chip die is greater than a width of the first semiconductor chip in the second direction.

5. The semiconductor package of claim 1, wherein the inter-chip die further comprises:
a connection via configured to penetrate the inter-chip die between the first surface and the second surface in the first direction.

6. The semiconductor package of claim 5, wherein when the inter-chip die is viewed in the first direction, the connection via is surrounded by the trench.

7. The semiconductor package of claim 5, wherein the trench comprises:
an outer side wall and an inner side wall facing each other in a second direction crossing the first direction, and
the connection via is inward of the inner side wall of the trench.

8. The semiconductor package of claim 5, wherein,
the trench includes an outer side wall, and
the connection via is outward of the outer side wall of the trench.

9. The semiconductor package of claim 8, further comprising:
a redistribution structure between the inter-chip die and the second semiconductor chip and connected to the connection via.

10. The semiconductor package of claim 5, wherein a height of the connection via is greater than a depth of the trench in the first direction.

11. The semiconductor package of claim 1, wherein an upper surface of the trench is between the first surface and the second surface in the first direction.

12. The semiconductor package of claim 1, wherein,
the first semiconductor chip includes a first chip upper connection pad on the upper surface of the first semiconductor chip,
the inter-chip die includes an inter-chip die lower pad on the first surface, and
the first chip upper connection pad and the inter-chip die lower pad are in contact with and connected to each other.

13. The semiconductor package of claim 1, wherein a width of the inter-chip die is greater than a width of the second semiconductor chip in a second direction crossing the first direction.

14. The semiconductor package of claim 1, wherein a width of the inter-chip die is equal to a width of the first semiconductor chip in a second direction crossing the first direction.

15. The semiconductor package of claim 1, wherein the second semiconductor chip includes a plurality of memory chips stacked in the first direction.

16. The semiconductor package of claim 1, wherein,
the first semiconductor chip includes a logic chip, and
the second semiconductor chip includes a memory chip.

17. A semiconductor package comprising:
a first semiconductor chip;
an inter-chip die on the first semiconductor chip in a first direction perpendicular to an upper surface of the first semiconductor chip; and
a second semiconductor chip on the inter-chip die in the first direction,
wherein the inter-chip die includes,
a first surface configured to face the first semiconductor chip;
a second surface configured to face the second semiconductor chip;
a trench at least partially defined by the inter-chip die, the trench recessed in the first surface toward the second surface; and
a connection via configured to electrically connect the first semiconductor chip and the second semiconductor chip and penetrate the inter-chip die in the first direction, and
an upper surface of the trench is between the first surface and the second surface in the first direction.

18. The semiconductor package of claim 17, wherein a width of the inter-chip die is equal to a width of the first semiconductor chip in a second direction crossing the first direction.

19. The semiconductor package of claim 17, wherein a height of the connection via is greater than a depth of the trench in the first direction.

20. A semiconductor package comprising:
a first semiconductor chip;
an inter-chip die on the first semiconductor chip in a first direction perpendicular to an upper surface of the first semiconductor chip and including a first surface configured to face the first semiconductor chip and a second surface opposite to the first surface;
a second semiconductor chip on the inter-chip die in the first direction;
a first chip bonding film between the inter-chip die and the first semiconductor chip and configured to cover the upper surface of the first semiconductor chip;
an inter-chip die lower bonding film between the first chip bonding film and the inter-chip die and configured to cover the first surface of the inter-chip die;
a molding film on the inter-chip die and configured to surround the second semiconductor chip;
a vertical flow path configured to penetrate the molding film in the first direction,
wherein the inter-chip die includes,
a trench at least partially defined by the inter-chip die, the trench recessed in the first surface toward the second surface, the trench configured to penetrate the inter-chip die lower bonding film; and
a connection via extended between the first surface and the second surface in the first direction,
the first chip bonding film is exposed into the trench, and
the vertical flow path communicates with the trench.
